(19) United States
(12) Patent Application Publication
(10) Pub. No.: US 2022/0069489 A1
(43) Pub. Date: Mar. 3, 2022

(54) CIRCUIT BOARD STRUCTURE AND MANUFACTURING METHOD THEREOF

(71) Applicant: Unimicron Technology Corp., Taoyuan City (TW)

(72) Inventors: John Hon-Shing Lau, Taoyuan City (TW); Chia-Yu Peng, Taoyuan City (TW); Kai-Ming Yang, Hsinchu County (TW); Pu-Ju Lin, Hsinchu City (TW); Cheng-Ta Ko, Taipei City (TW); Tzyy-Jang Tseng, Taoyuan City (TW)

(73) Assignee: Unimicron Technology Corp., Taoyuan City (TW)

(21) Appl. No.: 17/319,109

(22) Filed: May 13, 2021

Related U.S. Application Data
(63) Continuation-in-part of application No. 17/191,559, filed on Mar. 3, 2021.
(60) Provisional application No. 63/071,369, filed on Aug. 28, 2020.

(30) Foreign Application Priority Data
Jan. 12, 2021 (TW) 110101060

(51) Int. Cl. H01R 12/52; H01L 21/48; H01L 23/498; H01R 4/04; H01R 43/00

(52) U.S. Cl. CPC H01R 12/52; H01L 21/4857; H01L 23/49822; H01L 23/49866; H01R 4/04; H01R 43/00; H01L 23/49838

(57) ABSTRACT

A circuit board structure, including a redistribution circuit structure layer, a build-up circuit structure layer, and a connection structure layer, is provided. The redistribution circuit structure layer includes multiple first connecting pads. The build-up circuit structure layer is disposed on one side of the redistribution circuit structure layer and includes multiple second connecting pads. A line width and a line spacing of the redistribution circuit structure layer are smaller than a line width and a line spacing of the build-up circuit structure layer. The connection structure layer is disposed between the redistribution circuit structure layer and the build-up circuit structure layer, and includes a substrate and multiple conductive paste pillars penetrating the substrate. The first connecting pads are electrically connected to the second connecting pads respectively through the conductive paste pillars. The first connecting pads and the second connecting pads are respectively embedded in two opposite surfaces of the substrate.

### CROSS-REFERENCE TO RELATED APPLICATION

This application is a continuation-in-part application of and claims the priority benefit of U.S. application Ser. No.. 17/191,559, filed on Mar. 3, 2021, now pending. The prior U.S. application Ser. No. 17/191,559 claims the priority benefits of U.S. provisional application Ser. No. 63/071,369, filed on Aug. 28, 2020, and Taiwan application serial no. 110101060, filed on Jan. 12, 2021. The entirety of each of the above-mentioned patent applications is hereby incorporated by reference herein and made a part of this specification.

### BACKGROUND

### Technical Field

The disclosure relates to a substrate structure and a manufacturing method thereof, and particularly relates to a circuit board structure and a manufacturing method thereof.

### Description of Related Art

Generally speaking, two circuit boards with circuits or conductive structures are connected to each other through the solder joints and underfill is used to fill between two substrates to seal the solder joints. However, during the process of high-temperature reflow welding of solder, the circuit board with a larger area cannot be released due to stress, and larger warpage is likely to occur, thereby reducing the assembly yield between the two circuit boards.

### SUMMARY

The disclosure provides a circuit board structure, which does not need to use solder and underfill to reduce the cost and has better structural reliability.

The disclosure also provides a manufacturing method of a circuit board structure, which is configured to manufacture the circuit board structure.

The circuit board structure of the disclosure includes a redistribution circuit structure layer, a build-up circuit structure layer, and a connection structure layer. The redistribution circuit structure layer includes multiple first connecting pads. The build-up circuit structure layer is disposed on one side of the redistribution circuit structure layer and includes multiple second connecting pads. A line width and a line spacing of the redistribution circuit structure layer are smaller than a line width and a line spacing of the build-up circuit structure layer. The connection structure layer is disposed between the redistribution circuit structure layer and the build-up circuit structure layer, and includes a substrate and multiple conductive paste pillars penetrating the substrate. The first connecting pads are electrically connected to the second connecting pads respectively through the conductive paste pillars. The first connecting pads and the second connecting pads are respectively embedded in two opposite surfaces of the substrate.

In an embodiment of the disclosure, the redistribution circuit structure layer further includes multiple dielectric layers, at least one redistribution circuit, multiple conductive vias, and multiple chip pads. The dielectric layer and the redistribution circuit are alternately disposed. The first connecting pads, the redistribution circuit, and the chip pads are electrically connected through the conductive vias. A first dielectric layer and a second dielectric layer are located at outermost sides of the dielectric layers. The chip pads are buried in the first dielectric layer, the first connecting pads are located on the second dielectric layer, and the second dielectric layer directly contacts the substrate of the connection structure layer.

In an embodiment of the disclosure, a material of the dielectric layer includes a photosensitive dielectric material or an Ajinomoto build-up film (ABF).

In an embodiment of the disclosure, the circuit board structure further includes a surface treatment layer, which is disposed on the chip pads of the redistribution circuit structure layer. A material of the surface treatment layer includes electroless nickel electroless palladium immersion gold (ENEPIG), organic solderability preservative (OSP), or electroless nickel immersion gold (ENIG).

In an embodiment of the disclosure, the circuit board structure further includes a solder mask layer, which is disposed on a surface of the build-up circuit structure layer relatively far away from the connection structure layer and covers a part of the build-up circuit structure layer to define multiple solder ball pads.

The manufacturing method of the circuit board structure of the disclosure includes the following steps. A redistribution circuit structure layer including multiple first connecting pads is provided. A connection structure layer including a substrate and multiple conductive paste pillars penetrating the substrate is provided. The connection structure layer is in a B-stage state. A build-up circuit structure layer including multiple second connecting pads is provided. A line width and a line spacing of the redistribution circuit structure layer are smaller than a line width and a line spacing of the build-up circuit structure layer. The redistribution circuit structure layer, the connection structure layer, and the build-up circuit structure layer are pressed together, so that the connection structure layer is located between the redistribution circuit structure layer and the build-up circuit structure layer. The first connecting pads are electrically connected to the second connecting pads respectively through the conductive paste pillars, the first connecting pads and the second connecting pads are respectively embedded in two opposite surfaces of the substrate, and the connection structure layer, which consists of the substrate and the conductive paste pillars, changes from the B-stage state to a C-stage state.

In an embodiment of the disclosure, the step of providing the redistribution circuit structure layer including the first connecting pads includes the following steps. A temporary substrate and a release film located on the temporary substrate are provided. An insulating layer is formed on the release film. A core substrate is provided on the insulating layer. The core substrate includes a core layer and a first copper foil layer and a second copper foil layer located on two opposite sides of the core layer. The second copper foil layer is located between the core layer and the insulating layer. Multiple chip pads are formed on the first copper foil layer. A first dielectric layer is formed on the first copper foil layer. The first dielectric layer covers the chip pads and has multiple first openings, and the first openings expose a part of the chip pads. At least one redistribution circuit and multiple first conductive vias are formed. The redistribution circuit is disposed on the first dielectric layer, and the first conductive vias are respectively located in the first openings and are electrically connected to the redistribution circuit and the chip pads. A second dielectric layer is formed on the redistribution circuit. The second dielectric layer has multiple second openings, and the second openings expose a part of the redistribution circuit. The first connecting pads and multiple second conductive vias are formed. The first connecting pads are disposed on the second dielectric layer, and the second conductive vias are respectively located in the second openings and are electrically connected to the redistribution circuit and the first connecting pads. The temporary substrate and the release film are removed to expose the insulating layer.

In an embodiment of the disclosure, a material of the first dielectric layer and a material of the second dielectric layer include photosensitive dielectric materials or ABFs.

In an embodiment of the disclosure, after pressing the redistribution circuit structure layer, the connection structure layer, and the build-up circuit structure layer together, the manufacturing method further includes the following steps. The insulating layer and the core substrate are removed to expose the first dielectric layer of the redistribution circuit structure layer. A surface treatment layer is formed on the chip pads of the redistribution circuit structure layer. A material of the surface treatment layer includes ENEPIG, OSP, or ENIG.

In an embodiment of the disclosure, before pressing the redistribution circuit structure layer, the connection structure layer, and the build-up circuit structure layer together, the manufacturing method further includes the following steps. A solder mask layer is formed on a surface of the build-up circuit structure layer relatively far away from the connection structure layer. The solder mask layer covers a part of the build-up circuit structure layer to define multiple solder ball pads.

Based on the above, in the manufacturing method of the circuit board structure of the disclosure, the circuit board structure is formed through pressing the redistribution circuit structure layer, the connection structure layer, and the build-up circuit structure layer together. The first connecting pads of the redistribution circuit structure layer are electrically connected to the second connecting pads of the build-up circuit structure layer respectively through the conductive paste pillars of the connection structure layer, and the first connecting pads and the second connecting pads are respectively embedded in the two opposite surfaces of the substrate of the connection structure layer. As such, the manufacturing method of the circuit board structure of the disclosure does not need to use solder and underfill, which can effectively reduce the manufacturing cost of the circuit board structure. In addition, since no solder is used, the bonding yield between the redistribution circuit structure layer, the connection structure layer, and the build-up circuit structure layer can be effectively improved, thereby improving the structural reliability of the circuit board structure of the disclosure.

In order for the features and advantages of the disclosure to be more comprehensible, the following specific embodiments are described in detail in conjunction with the accompanying drawings.

### BRIEF DESCRIPTION OF THE DRAWINGS

FIG. 1A to FIG. 1P are schematic cross-sectional views of a manufacturing method of a circuit board structure according to an embodiment of the disclosure.

FIG. 2 is a schematic cross-sectional view of the circuit board structure of FIG. 1P disposed with a chip.

### DETAILED DESCRIPTION OF DISCLOSED EMBODIMENTS

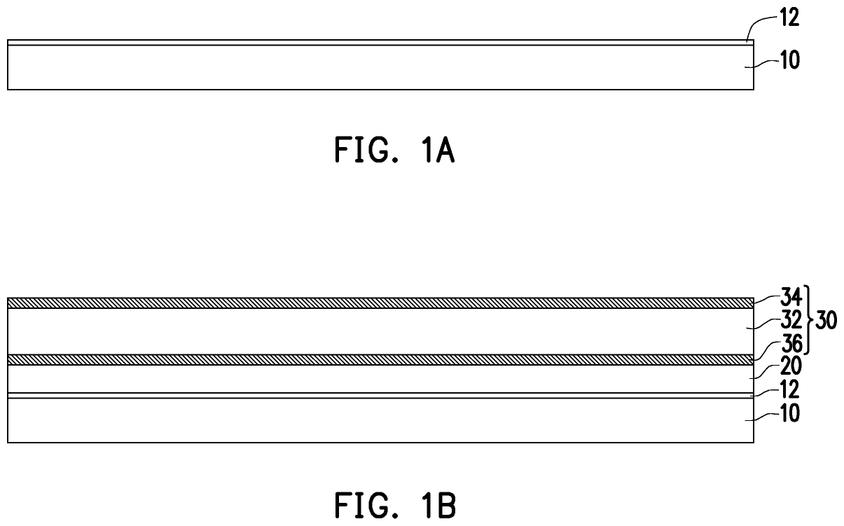

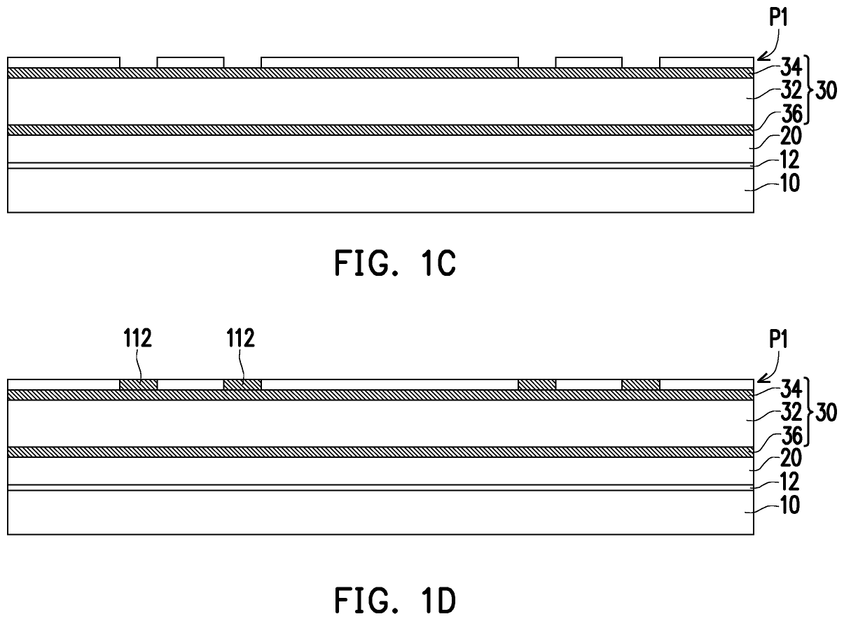

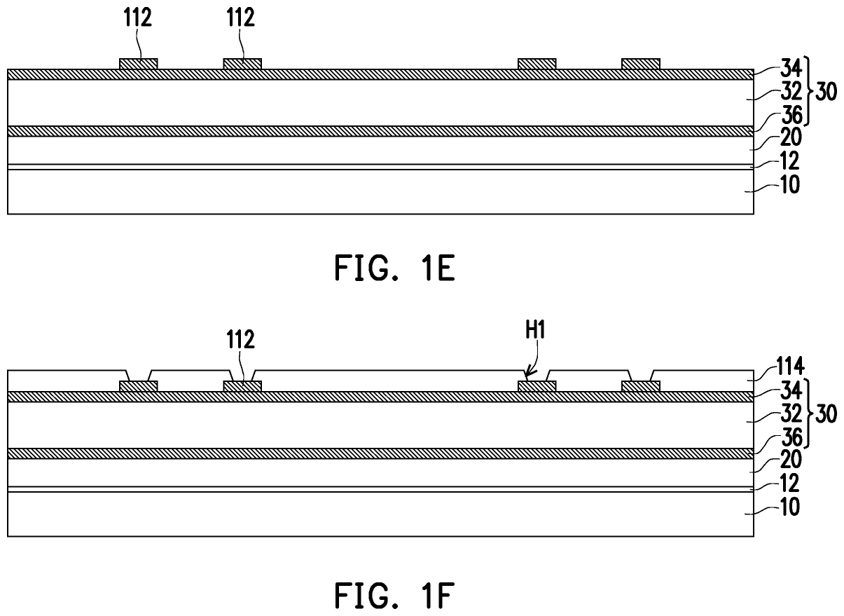

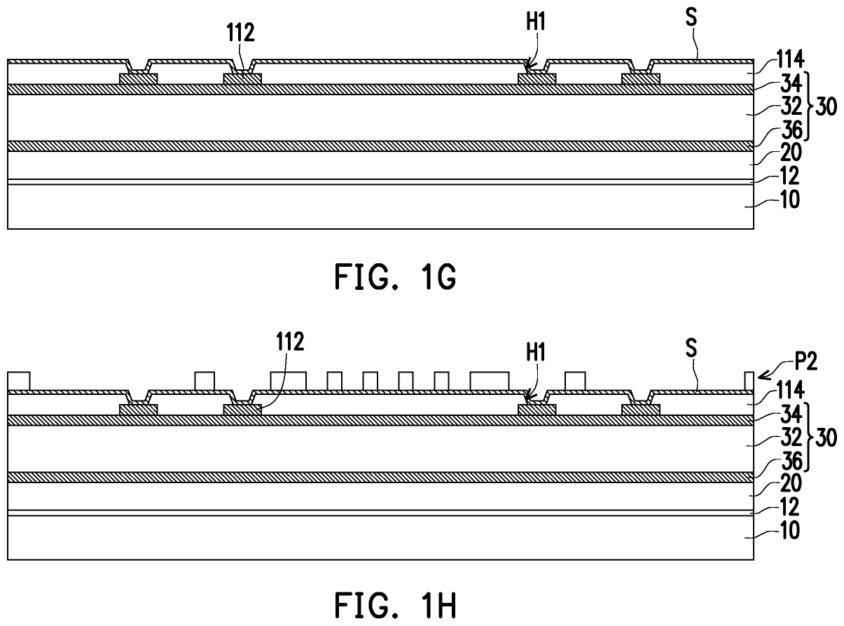

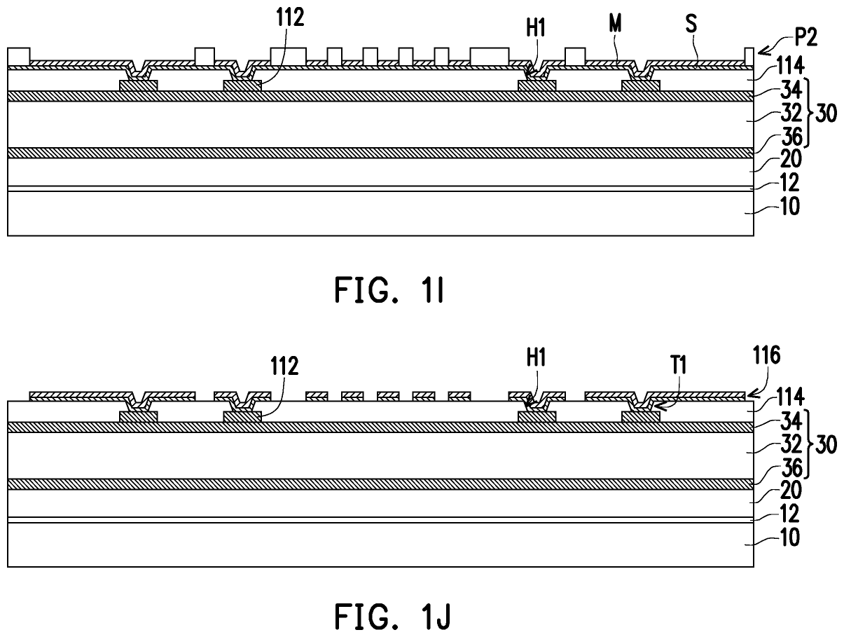

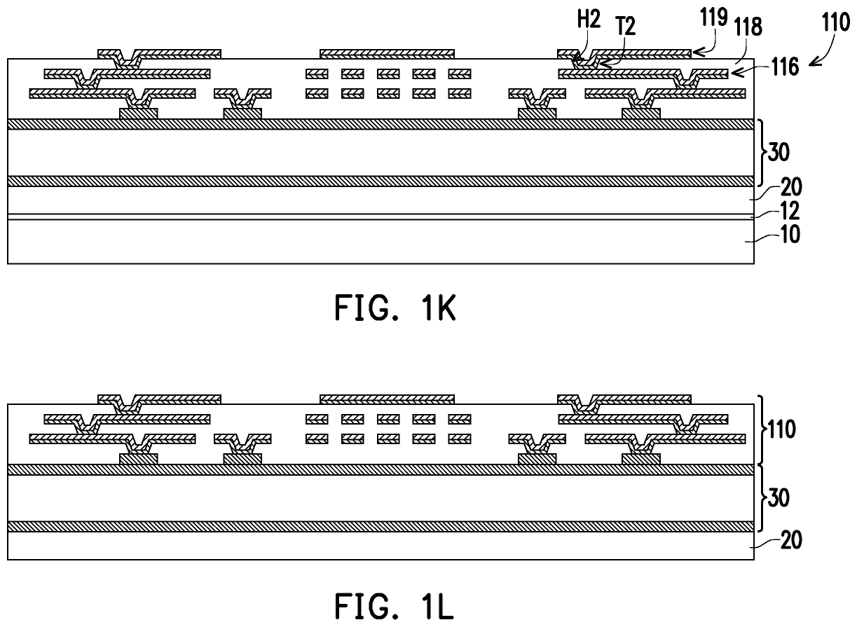

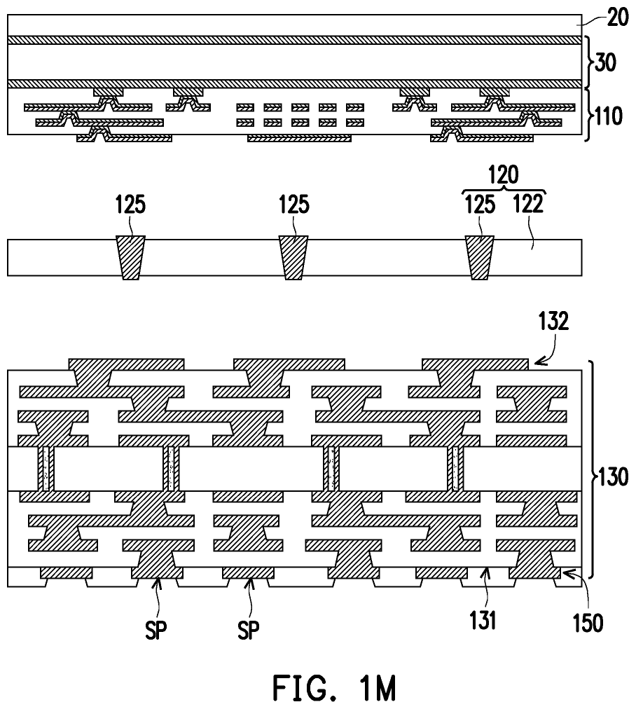

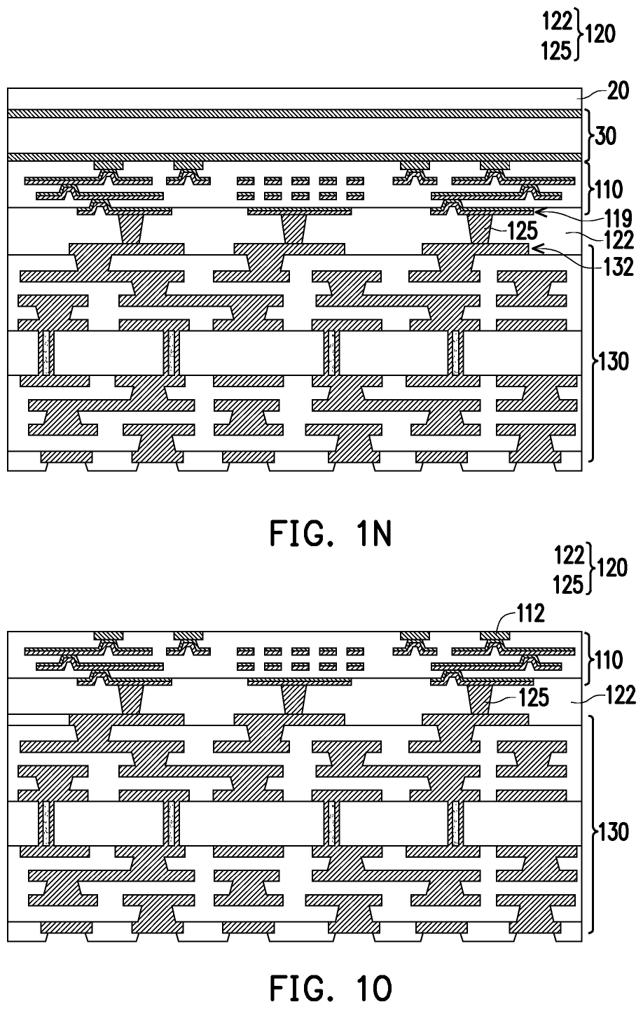

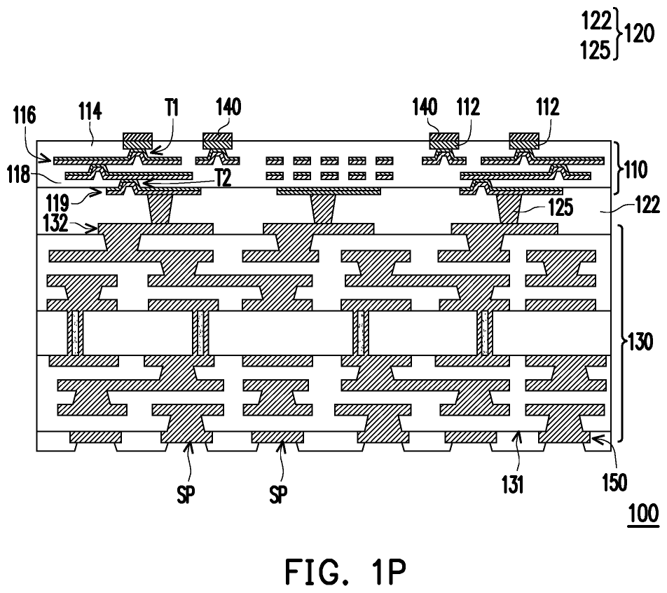

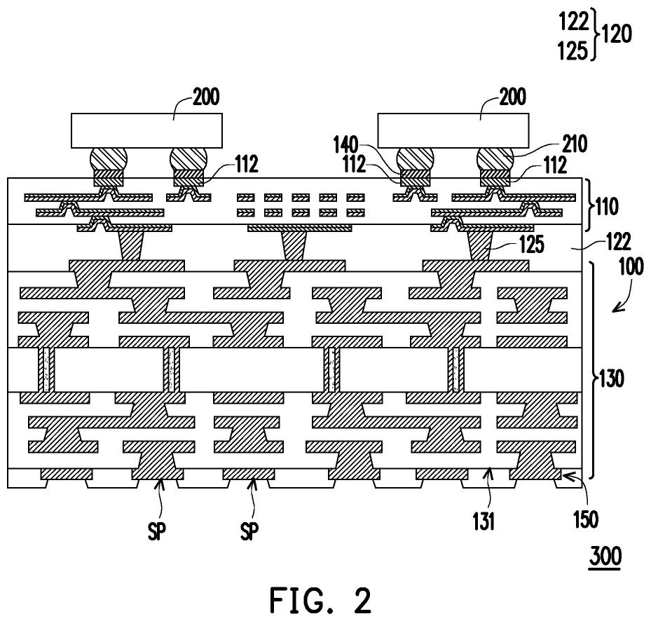

FIG. 1A to FIG. 1P are schematic cross-sectional views of a manufacturing method of a circuit board structure according to an embodiment of the disclosure. FIG. 2 is a schematic cross-sectional view of the circuit board structure of FIG. 1P disposed with chips. Regarding the manufacturing method of the circuit board structure of this embodiment, firstly, please refer to FIG. 1A. A temporary substrate (carrier) 10 and a release film 12 located on the temporary substrate 10 are provided. Here, the material of the temporary substrate 10 is, for example, glass or plastic, and the temporary substrate 10 is a substrate without circuit.

Next, please refer to FIG. 1B. An insulating layer 20 is formed on the release film 12. The material of the insulating layer 20 is, for example, an Ajinomoto build-up film (ABF), but not limited thereto.

Next, please refer to FIG. 1B again. A core substrate 30 is provided on the insulating layer 20. The core substrate 30 includes a core layer 32 and a first copper foil layer 34 and a second copper foil layer 36 located on two opposite sides of the core layer 32. In an embodiment, chemical-mechanical polishing is used to flatten the surface of the first copper foil layer 34. Here, the second copper foil layer 36 is located between the core layer 32 and the insulating layer 20.

Next, please refer to FIG. 1C. A pattern photoresist layer P1 is formed on the first copper foil layer 34. The pattern photoresist layer P1 exposes a part of the first copper foil layer 34.

Next, please refer to FIG. 1D. Multiple chip pads 112 are formed on the first copper foil layer 34. The chip pads 112 are located on the first copper foil layer 34 exposed by the pattern photoresist layer P1. Here, the chip pads 112 are formed by, for example, electroplating.

Next, please refer to FIG. 1D and FIG. 1E at the same time. The pattern photoresist layer P1 is removed to expose the first copper foil layer 34.

Next, please refer to FIG. 1F. A first dielectric layer 114 is formed on the first copper foil layer 34. The first dielectric layer 114 covers the chip pads 112 and has multiple first openings H1, and the first openings H1 expose a part of the chip pads 112. Here, the material of the first dielectric layer 114 is, for example, a photosensitive dielectric material or an ABF.

Next, please refer to FIG. 1G. A seed layer S is formed on the first dielectric layer 114. The seed layer S covers the first dielectric layer 114 and inner walls of the first openings H1, and is connected to the chip pads 112.

Next, please refer to FIG. 1H. A pattern photoresist layer P2 is formed on the seed layer S. The pattern photoresist layer P2 exposes a part of the seed layer S.

Next, please refer to FIG. 1I. A metal layer M is formed on the seed layer S exposed by the pattern photoresist layer P2. The metal layer M is formed by, for example, electroplating.

Next, please refer to FIG. 1J. The pattern photoresist layer P2 and the seed layer S located below the pattern photoresist layer P2 are removed to form a redistribution circuit 116 and first conductive vias T1. Here, the redistribution circuit 116 is located on the first dielectric layer 114, and the first conductive vias T1 are respectively located in the first openings H1 and are electrically connected to the redistribution circuit 116 and the chip pads 112.

Then, the steps of FIG. 1F to FIG. 1J may be repeated to form the required number of layers of the redistribution circuit 116 and the first conductive vias T1. The number of repetitions may be determined according to requirements of the user.

Next, please refer to FIG. 1K. A second dielectric layer 118 is formed on the redistribution circuit 116. The second dielectric layer 118 has multiple second openings H2, and the second openings H2 expose a part of the redistribution circuit 116. Here, the material of the second dielectric layer 118 is, for example, a photosensitive dielectric material or an ABF.

Next, please refer to FIG. 1K again. The same as the steps of FIG. 1G to FIG. 1J, first connecting pads 119 and multiple second conductive vias T2 are formed. Here, the first connecting pads 119 are disposed on the second dielectric layer 118, and the second conductive vias T2 are respectively located in the second openings H2 and are electrically connected to the redistribution circuit 116 and the first connecting pads 119. So far, the manufacturing of a redistribution circuit structure layer 110 including the first connecting pads 119 has been completed. Here, the redistribution circuit structure layer 110 is embodied as a redistribution circuit structure layer with thin circuits.

Next, please refer to FIG. 1K and FIG. 1L at the same time. The temporary substrate 10 and the release film 12 are removed to expose the insulating layer 20.

Next, please refer to FIG. 1M. A connection structure layer 120 including a substrate 122 and multiple conductive paste pillars 125 penetrating the substrate 122 is provided. The connection structure layer 120 is in a B-stage state. Here, the material of the substrate 122 is, for example, prepreg (PP), and the material of the conductive paste pillar 125 is, for example, conductive metal paste, which are coated by printing, which may have the effects of electrical conductivity and thermal conductivity, are suitable for bonding with any metal material.

Next, please refer to FIG. 1M again. A build-up circuit structure layer 130 including multiple second connecting pads 132 is provided. The line width and the line spacing of the redistribution circuit structure layer 110 are smaller than the line width and the line spacing of the build-up circuit structure layer 130. At this time, a solder mask layer 150 has been formed on a surface 131 of the build-up circuit structure layer 130 relatively far away from the connection structure layer 120. The solder mask layer 150 covers a part of the build-up circuit structure layer 130 to define multiple solder ball pads SP. Here, the build-up circuit structure layer 130 is embodied as a multi-layer circuit board.

It should be noted that the embodiment does not limit the sequence of providing the redistribution circuit structure layer 110, the connection structure layer 120, and the build-up circuit structure layer 130.

Next, please refer to FIG. 1N. The redistribution circuit structure layer 110, the connection structure layer 120, and the build-up circuit structure layer 130 are pressed together by hot pressing, so that the connection structure layer 120 is located between the redistribution circuit structure layer 110 and the build-up circuit structure layer 130. At this time, the insulating layer 20 and the core substrate 30 are still located on the redistribution circuit structure layer 110. In particular, the first connecting pads 119 are electrically connected to the second connecting pads 132 respectively through the conductive paste pillars 125, and the first connecting pads 119 and the second connecting pads 132 are respectively embedded in two opposite surfaces of the substrate 122. During hot pressing, the redistribution circuit structure layer 110 and the build-up circuit structure layer 130 directly contact the substrate 122 of the connection structure layer 120, and the conductive paste pillars 125 are squeezed to be deformed. At this time, since the substrate 122 and the conductive paste pillars 125 are not fully cured and has flexibility and adhesiveness, the redistribution circuit structure layer 110 and the build-up circuit structure layer 130 may be adhered together, and the first connecting pads 119 and the second connecting pads 132 are respectively squeezed into the substrate 122 to be embedded in the substrate 122. After pressing and curing, the substrate 122 and the conductive paste pillars 125 of the connection structure layer 120 changes from the B-stage state to a C-stage state.

After that, please refer to FIG. 1N and FIG. 1O at the same time. The insulating layer 20 and the core substrate 30 are removed to expose the first dielectric layer 112 of the redistribution circuit structure layer 110.

Finally, please refer to FIG. 1P. A surface treatment layer 140 is formed on the chip pads 112 of the redistribution circuit structure layer 110. Here, the material of the surface treatment layer 140 is, for example, electroless nickel electroless palladium immersion gold (ENEPIG), organic solderability preservative (OSP), or electroless nickel immersion gold (ENIG). So far, the manufacturing of the circuit board structure 100 has been completed.

In terms of structure, please refer to FIG. 1P again. In this embodiment, the circuit board structure 100 includes the redistribution circuit structure layer 110, the build-up circuit structure layer 130, and the connection structure layer 120. The redistribution circuit structure layer 110 includes the first connecting pads 119. The build-up circuit structure layer 130 is disposed on one side of the redistribution circuit structure layer 110 and includes the second connecting pads 132. The line width and the line spacing of the redistribution circuit structure layer 110 are smaller than the line width and the line spacing of the build-up circuit structure layer 130. The connection structure layer 120 is disposed between the redistribution circuit structure layer 110 and the build-up circuit structure layer 130, and includes the substrate 122 and the conductive paste pillars 125 penetrating the substrate 122. The first connecting pads 119 are electrically connected to the second connecting pads 132 respectively through the conductive paste pillars 125. The first connecting pads 119 and the second connecting pads 132 are respectively embedded in the two opposite surfaces of the substrate 122.

In detail, the redistribution circuit structure layer 110 of this embodiment further includes the chip pads 112, the first dielectric layer 114, the redistribution circuit 116, the second dielectric layer 118, the first conductive vias T1, and the second conductive vias T2. The first dielectric layer 114, the redistribution circuit 116, and the second dielectric layer 118 are alternately stacked. The first connecting pads 119, the redistribution circuit 116, and the chip pads 112 are electrically connected through the first conductive vias T1 and the second conductive vias T2. The chip pads 112 are buried in the first dielectric layer 114, the first connecting pads 119 are located on the second dielectric layer 118, and the second dielectric layer 118 directly contacts the substrate 122 of the connection structure layer 120.

In addition, the circuit board structure of this embodiment further includes the surface treatment layer 140 and the solder mask layer 150. The surface treatment layer 140 is disposed on the chip pads 112 of the redistribution circuit structure layer 110. The material of the surface treatment layer 140 is, for example, ENEPIG, OSP, or ENIG. The solder mask layer 150 is disposed on the surface 131 of the build-up circuit structure layer 130 relatively far away from the connection structure layer 120 and covers a part of the build-up circuit structure layer 130 to define the solder ball pads SP.

In short, since this embodiment forms the circuit board structure 100 through pressing the redistribution circuit structure layer 110, the connection structure layer 120, and the build-up circuit structure layer 130 together, there is no need to use solder joints and underfill, which can effectively reduce the manufacturing cost of the circuit board structure 100. In addition, since solder joints are not used, the bonding yield between the redistribution circuit structure layer 110, the connection structure layer 120, and the build-up circuit structure layer 130 can be effectively improved, thereby improving the structural reliability of the circuit board structure 100 of this embodiment.

In terms of application, please refer to FIG. 2. A chip 200 may be electrically connected to the chip pads 112 of the redistribution circuit structure layer 110 through a solder 210 to form a chip package structure 300.

In summary, in the manufacturing method of the circuit board structure of the disclosure, the circuit board structure is formed through pressing the redistribution circuit structure layer, the connection structure layer, and the build-up circuit structure layer together. The first connecting pads of the redistribution circuit structure layer are electrically connected to the second connecting pads of the build-up circuit structure layer respectively through the conductive paste pillars of the connection structure layer, and the first connecting pads and the second connecting pads are respectively embedded in the two opposite surfaces of the substrate of the connection structure layer. As such, the manufacturing method of the circuit board structure of the disclosure does not need to use solder joints and underfill, which can effectively reduce the manufacturing cost of the circuit board structure. In addition, since no solder is used, the bonding yield between the redistribution circuit structure layer, the connection structure layer, and the build-up circuit structure layer can be effectively improved, thereby improving the structural reliability of the circuit board structure of the disclosure.

Although the disclosure has been disclosed in the above embodiments, the embodiments are not intended to limit the disclosure. Persons skilled in the art may make some changes and modifications without departing from the spirit and scope of the disclosure. The protection scope of the disclosure shall be defined by the appended claims.

What is claimed is:

1. A circuit board structure, comprising:
a redistribution circuit structure layer, comprising a plurality of first connecting pads;
a build-up circuit structure layer, disposed on one side of the redistribution circuit structure layer and comprises a plurality of second connecting pads, wherein a line width and a line spacing of the redistribution circuit structure layer are smaller than a line width and a line spacing of the build-up circuit structure layer; and
a connection structure layer, disposed between the redistribution circuit structure layer and the build-up circuit structure layer, and comprises a substrate and a plurality of conductive paste pillars penetrating the substrate, wherein the first connecting pads are electrically connected to the second connecting pads respectively through the conductive paste pillars, and the first connecting pads and the second connecting pads are respectively embedded in two opposite surfaces of the substrate.

2. The circuit board structure according to claim 1, wherein the redistribution circuit structure layer further comprises a plurality of dielectric layers, at least one redistribution circuit, a plurality of conductive vias, and a plurality of chip pads, the dielectric layers and the at least one redistribution circuit are alternately disposed, the first connecting pads, the at least one redistribution circuit, and the chip pads are electrically connected through the conductive vias, a first dielectric layer and a second dielectric layer are located at outermost sides of the dielectric layers, the chip pads are buried in the first dielectric layer, the first connecting pads are located on the second dielectric layer, and the second dielectric layer directly contacts the substrate of the connection structure layer.

3. The circuit board structure according to claim 2, wherein a material of the dielectric layers comprises a photosensitive dielectric material or an Ajinomoto build-up film.

4. The circuit board structure according to claim 1, further comprising:
a surface treatment layer, disposed on the chip pads of the redistribution circuit structure layer, wherein a material of the surface treatment layer comprises electroless nickel electroless palladium immersion gold, organic solderability preservative, or electroless nickel immersion gold.

5. The circuit board structure according to claim 1, further comprising:
a solder mask layer, disposed on a surface of the build-up circuit structure layer relatively far away from the connection structure layer and covering a part of the build-up circuit structure layer to define a plurality of solder ball pads.

6. A manufacturing method of a circuit board structure, comprising:
providing a redistribution circuit structure layer comprising a plurality of first connecting pads;
providing a connection structure layer comprising a substrate and a plurality of conductive paste pillars penetrating the substrate, wherein the connection structure layer is in a B-stage state;
providing a build-up circuit structure layer comprising a plurality of second connecting pads, wherein a line width and a line spacing of the redistribution circuit structure layer are smaller than a line width and a line spacing of the build-up circuit structure layer; and
pressing the redistribution circuit structure layer, the connection structure layer, and the build-up circuit structure layer together, so that the connection structure layer is located between the redistribution circuit structure layer and the build-up circuit structure layer, wherein the first connecting pads are electrically connected to the second connecting pads respectively through the conductive paste pillars, the first connecting pads and the second connecting pads are respectively embedded in two opposite surfaces of the substrate, and the connection structure layer changes from the B-stage state to a C-stage state.

7. The manufacturing method of the circuit board structure according to claim 6, wherein the step of providing the redistribution circuit structure layer comprising the first connecting pads comprises:
providing a temporary substrate and a release film located on the temporary substrate;
forming an insulating layer on the release film;
providing a core substrate on the insulating layer, wherein the core substrate comprises a core layer and a first copper foil layer and a second copper foil layer located on two opposite sides of the core layer, and the second copper foil layer is located between the core layer and the insulating layer;
forming a plurality of chip pads on the first copper foil layer;
forming a first dielectric layer on the first copper foil layer, wherein the first dielectric layer covers the chip pads and has a plurality of first openings, and the first openings expose a part of the chip pads;
forming at least one redistribution circuit and a plurality of first conductive vias, wherein the at least one redistribution circuit is disposed on the first dielectric layer, and the first conductive vias are respectively located in the first openings and are electrically connected to the at least one redistribution circuit and the chip pads;
forming a second dielectric layer on the at least one redistribution circuit, wherein the second dielectric layer has a plurality of second openings, and the second openings expose a part of the at least one redistribution circuit;
forming the first connecting pads and a plurality of second conductive vias, wherein the first connecting pads are disposed on the second dielectric layer, and the second conductive vias are respectively located in the second openings and are electrically connected to the at least one redistribution circuit and the first connecting pads; and
removing the temporary substrate and the release film to expose the insulating layer.

8. The manufacturing method of the circuit board structure according to claim 7, wherein a material of the first dielectric layer and a material of the second dielectric layer comprise photosensitive dielectric materials or Ajinomoto build-up films.

9. The manufacturing method of the circuit board structure according to claim 7, wherein after pressing the redistribution circuit structure layer, the connection structure layer, and the build-up circuit structure layer together, the manufacturing method further comprises:
removing the insulating layer and the core substrate to expose the first dielectric layer of the redistribution circuit structure layer; and
forming a surface treatment layer on the chip pads of the redistribution circuit structure layer, wherein a material of the surface treatment layer comprises electroless nickel electroless palladium immersion gold, organic solderability preservative, or electroless nickel immersion gold.

10. The manufacturing method of the circuit board structure according to claim 6, wherein before pressing the redistribution circuit structure layer, the connection structure layer, and the build-up circuit structure layer together, the manufacturing method further comprises:
forming a solder mask layer on a surface of the build-up circuit structure layer relatively far away from the connection structure layer, wherein the solder mask layer covers a part of the build-up circuit structure layer to define a plurality of solder ball pads.
